(19) United States
(12) Patent Application Publication
(10) Pub. No.: US 2014/0138724 A1
(43) Pub. Date: May 22, 2014

(54) SUBSTRATE FOR MOUNTING OPTICAL SEMICONDUCTOR ELEMENT, METHOD FOR MANUFACTURING THE SUBSTRATE, AND OPTICAL SEMICONDUCTOR DEVICE

(71) Applicant: PANASONIC CORPORATION, Osaka (JP)

(72) Inventors: Takuma HITOMI, Kyoto (JP); Masashi KUBOTA, Tokyo (JP)

(73) Assignee: PANASONIC CORPORATION, Osaka (JP)

(21) Appl. No.: 14/070,199

(22) Filed: Nov. 1, 2013

(30) Foreign Application Priority Data
Nov. 2, 2012 (JP) 2012-242664

(51) Int. Cl. H01L 33/60; C03B 23/203

(52) U.S. Cl. CPC H01L 33/60; C03B 23/203
USPC 257/98; 428/212; 438/29; 65/36

(57) ABSTRACT

To manufacture a low-temperature co-fired ceramic/high-temperature co-fired ceramic laminated substrate by laminating a porous layer on a dense layer. The porous layer includes a first glass layer, a porous ceramic layer, and a second glass layer laminated on the dense layer in the stated order. The porous ceramic layer contains a glass component and ceramic filler, and has a porosity of 10% or more and 40% or less. A concentration of the glass component at least one of surfaces of the porous ceramic layer in a thickness direction thereof is higher than an average concentration of the glass component in the porous ceramic layer. The dense layer contains a ceramic component, and has a higher transverse rupture strength than the porous ceramic layer.

The disclosure of Japanese Patent Application No. 2012-242664 filed Nov. 2, 2012 including specification, drawings and claims is incorporated herein by reference in its entirety.

### BACKGROUND OF THE INVENTION

(1) Field of the Invention

The present invention relates to an optical semiconductor element-mounting substrate, a method for manufacturing the substrate, and an optical semiconductor device.

(2) Description of the Related Art

In recent years, optical semiconductor devices each including a substrate and an LED element mounted on the substrate have been used in various applications.

As a substrate on which an optical semiconductor element, such as an LED element, is mounted, a low-temperature fired ceramic (LTC) substrate has been developed. One example of the LTC substrate is a low-temperature co-fired ceramic (LTCC) substrate (Japanese Patent Application Publication No. 2011-243733). The LTCC substrate is manufactured by co-firing a porous ceramic substrate containing a glass component and ceramic filler, and a conductive member, such as a via and a wiring layer, at a low temperature. The LTCC substrate has good optical reflectance because of its high surface area. As the conductive member, Cu and Ag, which have a low melting point, can be used.

Meanwhile, a high-temperature fired ceramic (HTC) substrate manufactured by firing a ceramic substrate at a high temperature has been developed. The HTC substrate is a dense ceramic substrate. One example of the HTC substrate is a high-temperature co-fired ceramic (HTCC) substrate manufactured by co-firing a ceramic substrate and a conductive member at a high temperature.

Under such circumstances, a laminated substrate that is a laminate of one of the HTC layer and HTCC layer (collectively referred to as an HTC-containing layer), and one of the LTC layer and the LTCC layer (collectively referred to as an LTC-containing layer) has been developed. The laminated substrate thus developed has high thermal conductivity, high denseness, and high transverse rupture strength of the HTC-containing layer, as well as high optical reflectance of the LTC-containing layer. In addition, production costs can be lowered by reducing the thickness of the LTC-containing layer with the use of the HTC-containing layer.

FIG. 13A is a sectional view schematically showing the structure of a conventional optical semiconductor device 1X including an LTCC/HTCC laminated substrate. The device 1X includes: an LTCC/HTCC laminated substrate 10X; an LED element 2 mounted on the LTCC/HTCC laminated substrate 10X; an adhesive agent 5 bonding the LED element 2; bonding wires 3a and 3b; and a sealing resin 4 sealing the LED element 2. The LTCC/HTCC laminated substrate 10X is a laminate of a dense layer 11AX and a porous layer 11BX. The dense layer 11AX includes an HTC layer 110X, vias 100a and 100b, and wiring layers 101a and 101b. The porous layer 11BX includes an LTC layer 112X, a plurality of vias 100X, and wiring layers 101c to 101f.

### SUMMARY OF THE INVENTION

The laminated substrate including the HTC-containing layer and the LTC-containing layer, however, has the following problems.

Firstly, there is a need for further improvement in heat dissipation and reflectivity of the laminated substrate to respond to an increase in power of an LED element.

Secondly, the laminated substrate has insufficient strength, as problems like delamination between the HTC-containing layer and the LTC-containing layer and cracking of the LTC-containing layer can occur when heat generated during driving of the LED element is conducted to the laminated substrate, due to the difference in thermal expansion between the HTC-containing layer and the LTC-containing layer.

Thirdly, the LTC-containing layer can deteriorate by adherence of a residue of flux and a plating solution used during manufacturing of the substrate to a surface of the LTC-containing layer, which is a porous ceramic layer. In some cases, dust mixed in during manufacturing adheres to the surface of the LTC-containing layer.

FIG. 13B is an enlarged view of a portion A of FIG. 13A. If a flux residue and dust adhere to a pore of the LTC layer 112X as shown in FIG. 13B, optical reflectance of the LTC layer 112X can be lowered.

The present invention has been conceived in view of the above-mentioned problems, and aims to provide an optical semiconductor element-mounting substrate that includes a porous ceramic layer and a dense layer, and can exhibit good optical reflectance, provide strength to the porous ceramic layer, and have improved heat dissipation. The present invention also aims to provide a method for manufacturing the optical semiconductor element-mounting substrate and an optical semiconductor device.

In order to solve the above-mentioned problems, one aspect of the present invention is an optical semiconductor element-mounting substrate comprising a laminate of a dense layer and a porous layer, wherein the porous layer includes: a first glass layer on the dense layer; a porous ceramic layer on the first glass layer; and a second glass layer on the porous ceramic layer, the porous ceramic layer contains a glass component and ceramic filler, and has a porosity of 10% or more and 40% or less, and the dense layer contains a ceramic component, and has a higher transverse rupture strength than the porous ceramic layer.

In the optical semiconductor element-mounting substrate pertaining to one aspect of the present invention, the first glass layer is laminated on the dense layer containing the ceramic component. The ceramic component and the glass component typically have common thermal expansion. The glass component contained in the first glass layer is melted to highly adhere to the dense layer during firing. With this structure, high adhesion between the dense layer and the porous layer can be ensured even at a high temperature, thereby preventing delamination. Furthermore, since the dense layer contains the ceramic component so as to have a higher transverse rupture strength than the porous layer, the porous ceramic layer can be provided with strength, and the substrate can exhibit high strength as a whole.

In addition, since the second glass layer protects a surface of the porous ceramic layer, adherence of an unnecessary residue of flux and a plating solution to the surface of the porous ceramic layer during manufacturing, and adherence of dust and the like can be prevented. Thus, surface properties of the porous ceramic layer can be maintained, and lowering of optical reflectance can be prevented.

The porous ceramic layer contains the ceramic filler, which has high reflectivity to visible light, and contains a large number of pores. Thus, even when the thickness of the porous ceramic layer is reduced, the porous ceramic layer can exhibit good optical reflectance. By reducing the thickness of the porous ceramic layer to suppress thermal resistance of the substrate, heat dissipation can be improved.

### BRIEF DESCRIPTION OF THE DRAWINGS

These and other objects, advantages, and features of the invention will become apparent from the following description thereof taken in conjunction with the accompanying drawings, which illustrate specific embodiments of the present invention.

FIG. 1 is an outline view showing the structure of an optical semiconductor device 1 according to Embodiment 1.

FIG. 2 is a sectional view schematically showing an inner structure of the optical semiconductor device 1.

FIG. 3 is a partial enlarged view showing a cross section of an LTCC/HTCC laminated substrate 10.

FIG. 4A is a photomicrograph of an LTC layer 112.

FIG. 4B is a photomicrograph of a conventional porous layer.

FIG. 5 is a graph showing relations between visible light wavelength and reflectance according to working examples and a comparative example.

FIG. 6 is a graph showing a range of a preferable glass blending ratio in the LTC layer 112.

FIG. 7 shows steps of manufacturing the LTCC/HTCC laminated substrate 10.

FIGS. 8A-8D are sectional views schematically showing a manufacturing process of a porous layer intermediate 22.

FIGS. 9A-9D are sectional views schematically showing a manufacturing process of a dense layer intermediate 35.

FIGS. 10A and 10B are sectional views schematically showing a manufacturing process of the LTCC/HTCC laminated substrate 10.

FIG. 11A is a sectional view showing the structure of each substrate according to Embodiment 2.

FIG. 11B is a sectional view showing the structure of each substrate according to Embodiment 3.

FIG. 11C is a sectional view showing the structure of each substrate according to Embodiment 4.

FIG. 12A is a sectional view showing the structure of each substrate according to Embodiment 5.

FIG. 12B is a sectional view showing the structure of each substrate according to Embodiment 6.

FIG. 13A is a sectional view schematically showing the structure of a conventional optical semiconductor device.

FIG. 13B is an enlarged view of a portion A of FIG. 13A.

### DESCRIPTION OF THE PREFERRED EMBODIMENTS

<Aspects of Invention>

One aspect of the present invention is an optical semiconductor element-mounting substrate comprising a laminate of a dense layer and a porous layer, wherein the porous layer includes: a first glass layer on the dense layer; a porous ceramic layer on the first glass layer; and a second glass layer on the porous ceramic layer, the porous ceramic layer contains a glass component and ceramic filler, and has a porosity of 10% or more and 40% or less, and the dense layer contains a ceramic component, and has a higher transverse rupture strength than the porous ceramic layer.

As another aspect of the present invention, the porous ceramic layer may be made of a low-temperature fired ceramic containing the glass component and the ceramic filler.

As yet another aspect of the present invention, a difference in thermal expansion coefficient between the porous ceramic layer and the dense layer may be 1×10⁻⁶/K or less.

As yet another aspect of the present invention, the porous layer may have a reflectance of 85% or more to light having a wavelength of 380 nm or more and 780 nm or less.

As yet another aspect of the present invention, the porous ceramic layer may have a thickness of 20 μm or more and 150 μm or less.

As yet another aspect of the present invention, a concentration of the glass component at surfaces of the porous ceramic layer in a thickness direction thereof may be higher than an average concentration of the glass component in the porous ceramic layer.

As yet another aspect of the present invention, the glass component may be at least one material selected from the group consisting of borosilicate glass, silica glass, soda-lime glass, borosilicate zinc glass, aluminoborosilicate glass, aluminosilicate glass, and phosphate glass.

As yet another aspect of the present invention, the ceramic filler may be at least one material selected from the group consisting of alumina, zirconia, titanium oxide, zinc oxide, forsterite, enstatite, celsian, slawsonite, anorthite, diopside, gahnite, spinel, willemite, mullite, cordierite, and solid solutions of any of the stated materials.

As yet another aspect of the present invention, the dense layer may be made of a high-temperature fired ceramic containing the ceramic component.

As yet another aspect of the present invention, the high-temperature fired ceramic may be at least one material selected from the group consisting of alumina and aluminum nitride.

As yet another aspect of the present invention, the porous layer may include a cavity-structure portion having a depth in a thickness direction of the porous layer.

As yet another aspect of the present invention, the porous layer may have at least one via, each via penetrating through the porous layer in a thickness direction thereof.

As yet another aspect of the present invention, a first porous ceramic layer, a third glass layer, a second porous ceramic layer, and a fourth glass layer may be located on the porous layer in the stated order, and a wiring layer may be located at a part of an interface between the second glass layer and the first porous ceramic layer.

Another aspect of the present invention is an optical semiconductor device comprising: the optical semiconductor element-mounting substrate of the present invention described as any of the above-mentioned aspects; and an optical semiconductor element mounted on the optical semiconductor element-mounting substrate.

Yet another aspect of the present invention is a method for manufacturing an optical semiconductor element-mounting substrate, comprising: interposing a green sheet between a pair of glass-containing sheets to form a porous layer intermediate, the green sheet containing ceramic filler and a glass component; laminating a dense layer intermediate containing a ceramic component on one of the glass-containing sheets; firing the porous layer intermediate and the dense layer intermediate to respectively form a porous layer and a dense layer, the porous layer including a pair of glass layers and a porous ceramic layer interposed between the pair of glass layers, wherein in forming the porous layer intermediate, the green sheet has a glass blending ratio, a glass softening point, and a particle size of the ceramic filler each adjusted so that the porous ceramic layer has a porosity of 10% or more and 40% or less, and in forming the dense layer, a material providing the dense layer with a higher transverse rupture strength than the porous ceramic layer is used as the ceramic component.

As yet another aspect of the present invention, the glass blending ratio may be 10 wt % or more and 30 wt % or less, the glass softening point may be lower than a firing temperature in firing the porous layer intermediate and the dense layer intermediate, and be higher than a temperature that is lower than the firing temperature by 100° C., and the particle size of the ceramic filler may be 0.1 μm or more and 0.3 μm or less.

As yet another aspect of the present invention, in firing the porous layer intermediate, the porous ceramic layer may be formed by low-temperature co-firing.

As yet another aspect of the present invention, each of the glass-containing sheets may be a glass plate having a thickness of 5 μm or more and 20 μm or less.

As yet another aspect of the present invention, a thickness of the green sheet may be adjusted so that the porous ceramic layer has a thickness of 10 μm or more and 150 μm or less.

As yet another aspect of the present invention, a glass component contained in each of the glass-containing sheets may be infiltrated into the green sheet in firing the porous layer intermediate, so that a concentration of the glass component at surfaces of the porous ceramic layer in a thickness direction thereof is higher than an average concentration of the glass component in the porous ceramic layer.

As yet another aspect of the present invention, the glass component may be at least one material selected from the group consisting of borosilicate glass, silica glass, soda-lime glass, borosilicate zinc glass, aluminoborosilicate glass, aluminosilicate glass, and phosphate glass.

As yet another aspect of the present invention, the ceramic filler may be at least one material selected from the group consisting of alumina, zirconia, titanium oxide, zinc oxide, forsterite, enstatite, celsian, slawsonite, anorthite, diopside, gahnite, spinel, willemite, mullite, cordierite, and solid solutions of any of the stated materials.

As yet another aspect of the present invention, the ceramic component may be at least one material selected from the group consisting of alumina and aluminum nitride.

Yet another aspect of the present invention is a method for manufacturing an optical semiconductor device, comprising mounting a light-emitting element above the porous layer included in the optical semiconductor element-mounting substrate manufactured by the method for manufacturing an optical semiconductor element-mounting substrate of the present invention described as any of the above-mentioned aspects.

### Embodiment 1

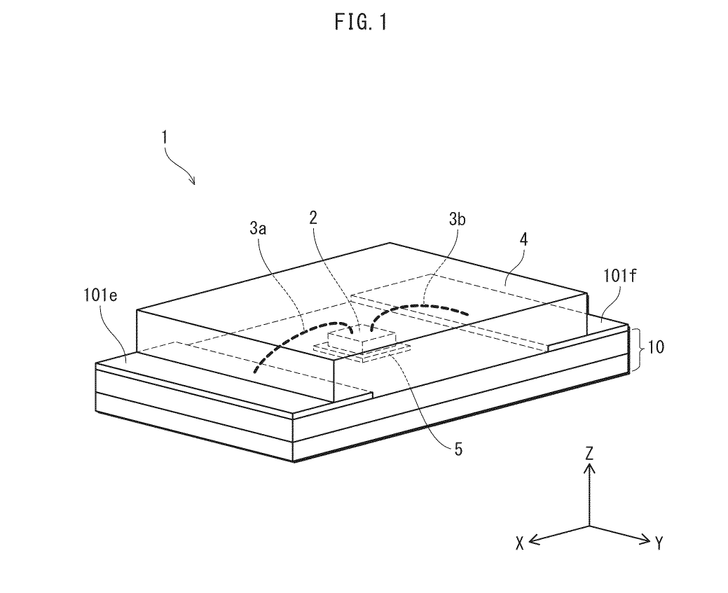

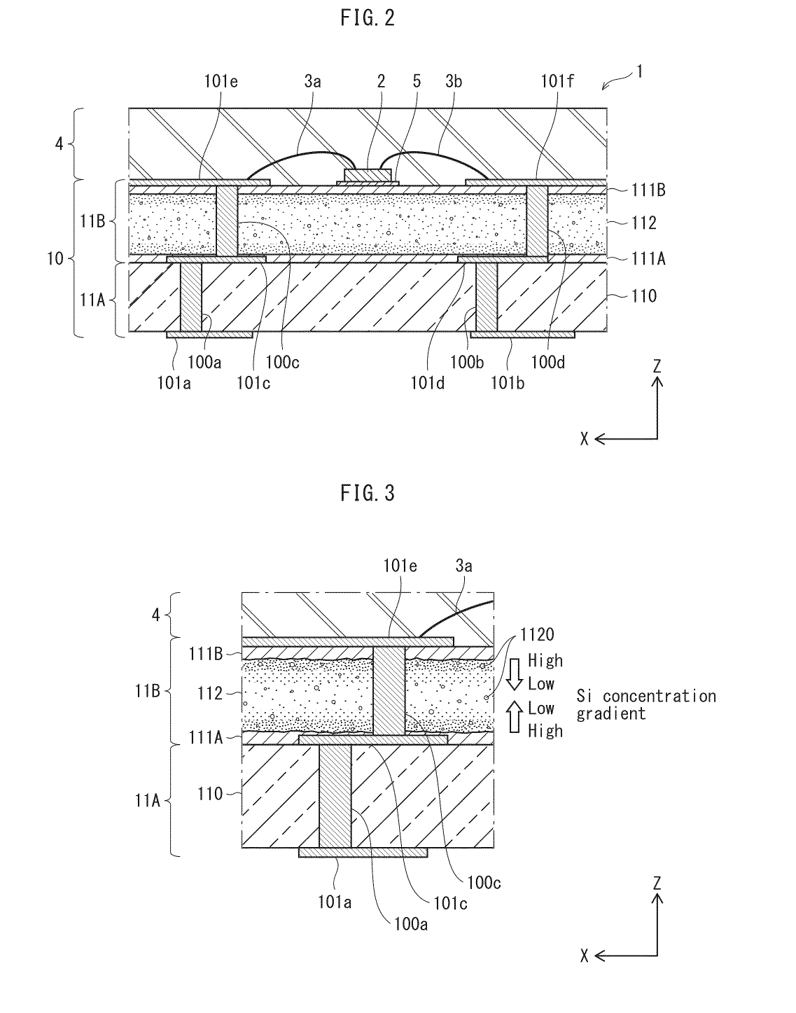

FIG. 1 is an outline view showing the structure of an optical semiconductor device 1 (hereinafter, simply referred to as a “device 1”) according to Embodiment 1 of the present invention. FIG. 2 is a sectional view schematically showing a portion of the device 1.

In appearance, the device 1 includes an LTCC/HTCC laminated substrate 10 and a transparent sealing resin 4 disposed on an upper surface of the LTCC/HTCC laminated substrate 10. Inside the sealing resin 4, an LED element 2 is mounted on the surface of the LTCC/HTCC laminated substrate 10 with an adhesive agent 5. The LED element 2 is electrically connected to wiring layers 101e and 101f through bonding wires 3a and 3b, respectively (FIG. 1).

The device 1 includes the LTCC/HTCC laminated substrate 10, the LED element 2, the bonding wires 3a and 3b, the sealing resin 4, and the adhesive agent 5.

The following describes each of these components.

[LED Element 2]

The LED element is a light-emitting element as a light source of the device 1. As an example of the LED element 2, a blue LED element made of InGaN is used herein.

[Bonding Wires 3a and 3b]

The bonding wires 3a and 3b are fine wires electrically connecting electrodes of the LED element 2 to the respective wiring layers 101e and 101f. The bonding wires 3a and 3b are made for example of an Au material.

[Sealing Resin 4]

The sealing resin 4 covers the LED element 2 and the bonding wires 3a and 3b for protection. The sealing resin 4 transmits light emitted from the LED element 2 during driving to the exterior of the sealing resin 4. The sealing resin 4 is made for example of a heat-resistant resin, such as an acrylic silicone resin.

[Adhesive Agent 5]

The adhesive agent 5 is used for the purpose of mounting the LED element 2 on an uppermost surface of the LTCC/HTCC laminated substrate 10. The adhesive agent 5 contains a heat-resistant material.

[LTCC/HTCC Laminated Substrate 10]

The LTCC/HTCC laminated substrate 10 is a laminate of a dense layer 11A and a porous layer 11B each including a ceramic as a major component. In the device 1, the porous layer 11B is laminated on the dense layer 11A.

(i) Dense Layer 11A

The dense layer 11A is an HTCC layer manufactured through firing at a relatively high temperature of 1200° C. or higher. The dense layer 11A includes wiring layers 101a and 101b, vias 100a and 100b, and an HTC layer 110.

The wiring layers 101a and 101b are each made of a metal material, such as Ag and Cu, excelling in heat dissipation and conductivity. The wiring layers 101a and 101b are disposed on a lower surface of the dense layer 11A, and are used as electrode terminals of the device 1. As shown in FIG. 2, the wiring layers 101a and 101b are electrically connected to the LED element 2 through the vias 100a and 100b, the wiring layers 101c and 101d, vias 100c and 100d, the wiring layers 101e and 101f, and the bonding wires 3a and 3b, respectively, in the stated order.

The vias 100a and 100b are each made of a metal material, such as Ag, excelling in heat dissipation and conductivity. The vias 100a and 100b each penetrate the HTC layer 110 in a thickness (Z) direction thereof. The vias 100a and 100b are used to electrically connect the LED element 2 to the wiring layers 101a and 101b. The vias 100a and 100b are also used to conduct heat generated by the LED element 2 during driving to a lower surface of the HTC layer 110.

The dense layer 11A contains, as a major component, a ceramic material including at least one material selected from the group consisting of alumina (Al₂O₃) and aluminum nitride (AlN). The dense layer 11A herein contains Al₂O₃ as a major component. The HTC layer 110 contains ceramic particles tightly bound by high-temperature firing. The dense layer 11A thus has good rigidity (a higher transverse rupture strength than the porous layer 11B). The HTC layer 110 is a heat dissipation layer having good heat dissipation (high thermal conductivity). In the LTCC/HTCC laminated substrate 10, the dense layer 11A is used as a major heat dissipation means and a base substrate for providing strength to the LTCC/HTCC laminated substrate 10.

(ii) Porous Layer 11B

The porous layer 11B is an LTCC layer manufactured through firing at a relatively low temperature of 1000° C. or lower. The porous layer 11B is manufactured by co-firing wiring layers 101c, 101d, 101e, and 101f, vias 100c and 100d, an LTC layer 112, a first glass layer 111A, and a second glass layer 111B. The porous layer 11B has high optical reflectance, and is used as a light reflection layer.

The wiring layers 101c, 101d, 101e, and 101f have similar structures to the wiring layers 101a and 101b. Each of the wiring layers 101c and 101d is a lowermost surface of the porous layer 11B, and each of the wiring layers 101e and 101f is an uppermost surface of the porous layer 11B.

The vias 100c and 100d have similar structures to the vias 100a and 100b. The vias 100c and 100d each penetrate the LTC layer 112 in a thickness direction thereof.

Each of the first glass layer 111A and the second glass layer 111B is a transparent layer made of a glass component, and transmits visible light. The first glass layer 111A and the second glass layer 111B are each set so as to have a thickness of approximately 10 μm or more and 20 μm or less.

The first glass layer 111A is a lower portion of the porous layer 11B, and disposed so as to be laminated on the dense layer 11A. The first glass layer 111A is closely attached to a surface of the dense layer 11A by firing during manufacturing.

The second glass layer 111B is an upper portion of the porous layer 11B, and disposed so as to be laminated on the LTC layer 112. The second glass layer 111B covers an upper surface of the LTC layer 112 for protection. With this structure, a large number of pores 1120 existing at the surface of the LTC layer 112 are buried in the second glass layer 111B.

The LTC layer 112 is a porous ceramic layer, and contains ceramic filler (fine particles) and a glass component. Ceramic filler particles are bound by firing to form a cluster. The porous structure is thus formed. The glass component is a binder for the ceramic filler. In the porous layer 11B, the ceramic filler mainly performs a light reflection function. In the porous layer 11B, the LTC layer 112, and the vias 100c and 100d constitute an LTCC layer. Since the porous layer 11B contains a large number of pores 1120 in the LTC layer 112, the porous layer 11B also serves as a low dielectric constant layer.

FIG. 3 is a partial enlarged view showing a cross section of the LTCC/HTCC laminated substrate 10. A large number of pores 1120 each having a diameter of several micrometers exist at surfaces and on the inside of the LTC layer 112. The LTC layer 112 is set to have a porosity of 10% or more and 40% or less.

The LTC layer 112 has a graded composition in which a glass component concentration gradually decreases from surfaces of the LTC layer 112 in the thickness (Z) direction thereof to the inside of the LTC layer 112 by infiltration of the glass component of each of the first glass layer 111A and the second glass layer 111B into the LTC layer 112 during manufacturing. FIG. 3 schematically shows concentration distribution of a major component of a glass (Si) in the LTC layer 112.

Specifically, when a cross-section of the LTC layer 112, which has a thickness of approximately 100 μm, taken in the thickness (Z) direction thereof is viewed in a microscope, in portions from the surfaces of the LTC layer 112 in the thickness (Z) direction thereof to a depth of 20 μm, glass accounts for 70% or more of a total area per unit area, and there exists a dense glass layer. In an inside portion in a depth of more than 20 μm in the thickness (Z) direction, glass accounts for 10% or more and 40% or less of the total area per unit area, and there exists a layer that is a mixture of glass and ceramic filler in a certain ratio. Since the LTC layer 112 contains a large quantity of glass component at and around interfaces between the LTC layer 112 and the first glass layer 111A, and between the LTC layer 112 and the second glass layer 111B, high adhesion between the LTC layer 112 and the first glass layer 111A, and between the LTC layer 112 and the second glass layer 111B can be ensured.

Although the graded composition of the LTC layer 112 containing the glass component is not essential in the present invention, it is desirable that the glass component concentration at the surfaces of the LTC layer 112 in the thickness (Z) direction thereof be at least higher than an average glass component concentration in the LTC layer 112, as high adhesion between the LTC layer 112 and the first glass layer 111A, and between the LTC layer 112 and the second glass layer 111B can be ensured.

A portion of the LTC layer 112 containing a smaller quantity of glass component than the other portions functions as a portion that can contribute to efficient light reflection, as the portion contains a larger amount of ceramic filler instead.

The ceramic filler contained in the LTC layer 112 is at least one material selected from the group consisting of alumina, zirconia, titanium oxide, zinc oxide, forsterite, enstatite, celsian, slawsonite, anorthite, diopside, gahnite, spinel, willemite, mullite, cordierite, and solid solutions of any of the stated materials.

The glass component contained in the LTC layer 112 is at least one material selected from the group consisting of borosilicate glass, silica glass, soda-lime glass, borosilicate zinc glass, aluminoborosilicate glass, aluminosilicate glass, and phosphate glass.

The LTC layer 112 preferably has a thickness of 20 μm or more and 150 μm or less. The LTC layer 112 with a thickness of more than 150 μm can have increased brittleness. On the other hand, the LTC layer 112 with a thickness of less than 20 μm can have insufficient optical reflectance.

Component distribution in the LTC layer 112 is actually confirmed, for example, by observing a cross-section of the LTC layer 112 with an SEM, and performing EDS linear analysis.

<Advantageous Effects Provided by Device 1>

The device 1 having the above-mentioned structure provides the following advantageous effects.

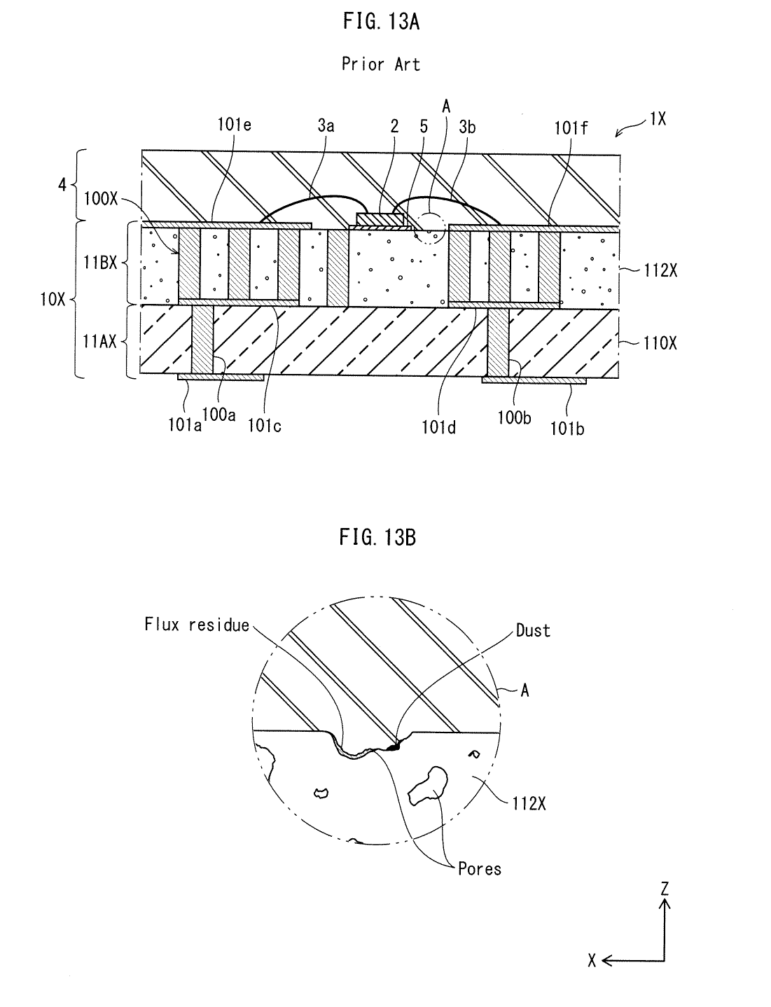

(i) The second glass layer 111B included in the LTCC/HTCC laminated substrate 10 protects a surface of the LTC layer 112, thereby preventing a problem of deterioration of the LTC layer 112 caused due to direct adherence of an unnecessary residue of flux and a plating solution to the surface of the LTC layer 112 during manufacturing, and a problem of direct adherence of dust to the surface of the LTC layer 112 (see FIG. 13B). Thus, good optical reflectance of the LTC layer 112 is maintained over a long time period.

(ii) The LTC layer 112 contains a large number of pores with a porosity of 10% or more and 40% or less, and thus has a high surface area. The LTC layer 112 also contains the ceramic filler made of a predetermined material described above. With this structure, the LTC layer 112 can exhibit good optical reflectance even when being relatively thin.

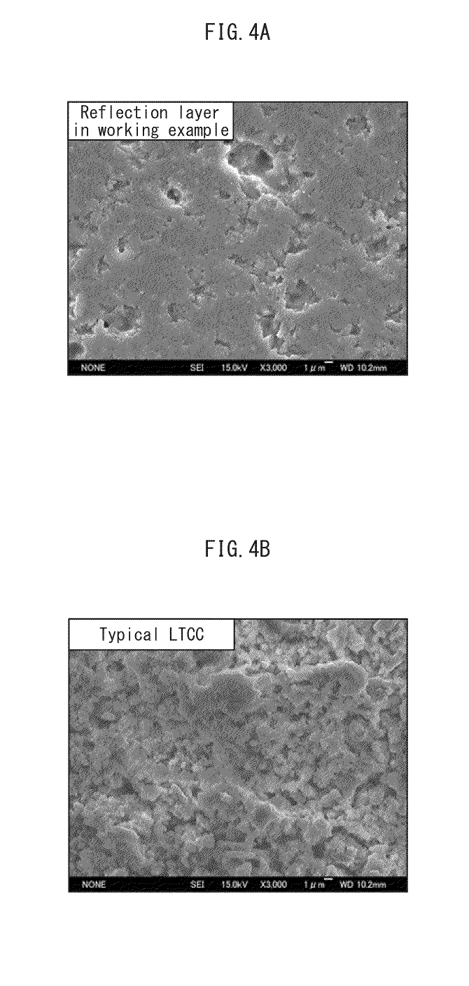

FIG. 4A is a photomicrograph of the LTC layer 112 (with a porosity of approximately 40%), and FIG. 4B is a photomicrograph of a typical (conventional) LTCC layer (with a porosity of approximately less than 5%). As shown in FIG. 4A, the LTC layer 112 contains a large number of pores, and thus has a substantially high surface area. During driving of the device 1, the LTC layer 112 thus efficiently reflects light emitted from the LED element 2 via the transparent second glass layer 111A, thereby contributing to improvement in luminous efficiency of the LED element 2.

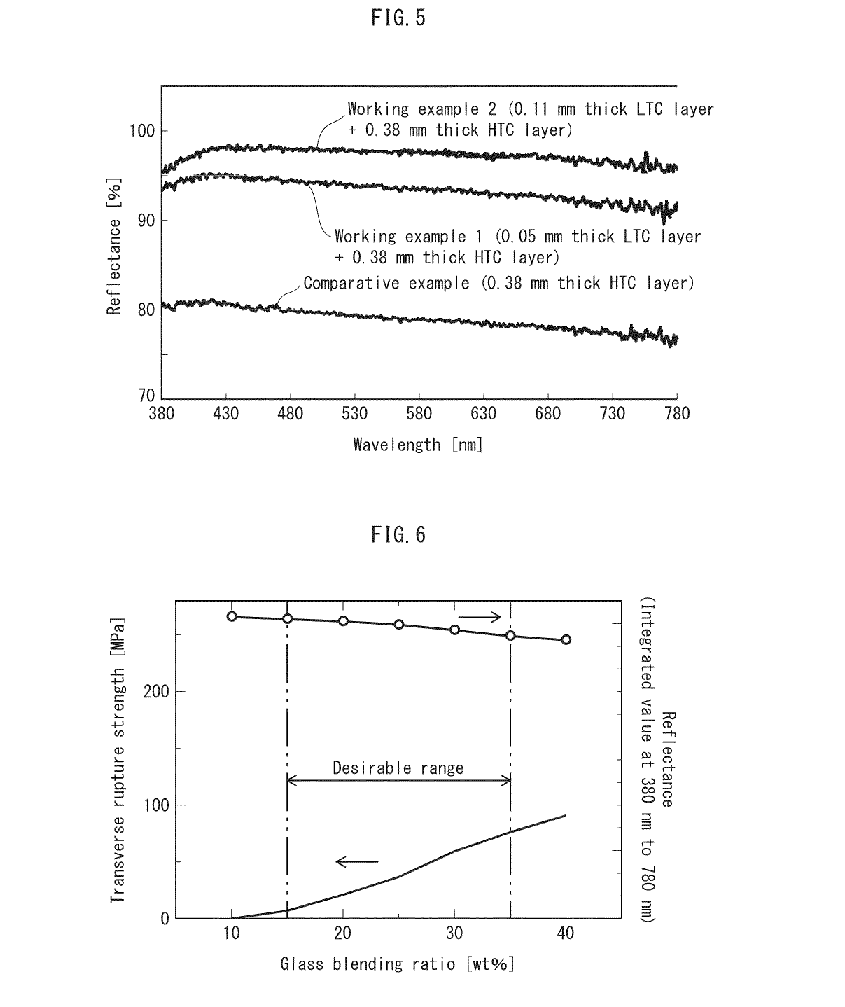

FIG. 5 is a graph showing optical reflectance of each of a working example 1 (the LTC layer 112 with a thickness of 0.05 mm+the HTC layer 110 with a thickness of 0.38 mm), a working example 2 (the LTC layer 112 with a thickness of 0.11 mm+the HTC layer 110 with a thickness of 0.38 mm), and a comparative example (the HTC layer 110 with a thickness of 0.38 mm) to light in each wavelength range. As shown in FIG. 5, the working examples 1 and 2 each have good reflectance to light over a wide wavelength range, and, in particular, have a reflectance of 99% to light having a wavelength of approximately 400 nm. The working examples 1 and 2 each have a reflectance of 85% or more to light having a wavelength of 380 nm to 780 nm. The optical reflectance of the typical LTC layer significantly reduces when the typical LTC layer is made thinner. However, the working examples 1 and 2 each have much better optical reflectance than the comparative example, even though the working examples 1 and 2 are each much thinner than the comparative example.

An increase in number of pores contained in the LTC layer increases a risk of a contaminant mixed or adhering into a pore during manufacturing of the substrate (see FIG. 13B). In Embodiment 1, however, such a problem is properly prevented, because the first glass layer 111A and the second glass layer 111B are laminated on both surfaces of the LTC layer 112.

(iii) Thermal resistance Rth (° C.·cm/W) of the LTCC/HTCC laminated substrate 10 is expressed by the equation Rth=substrate thickness/cross section/thermal conductivity. Accordingly, by taking advantage of the properties of the LTC layer 112 shown in FIG. 5, the LTC layer 112 is made thinner and includes the porous layer 11B having improved heat dissipation, while exhibiting good optical reflectance.

The porous layer 11B having high heat dissipation can reduce the number of vias provided in the porous layer 11B and the dense layer 11A for heat dissipation, or can even omit formation of such vias. Furthermore, by reducing the thickness of the LTC layer 112, material costs for the LTC layer 112 can be reduced. The number of steps of manufacturing the LTCC/HTCC laminated substrate 10 can thus be reduced to improve yield, and production costs can be lowered.

(iv) The porous layer 11B is laminated over the dense layer 11A having a higher transverse rupture strength than the porous layer 11B, thereby providing strength to the LTC layer 112. This structure can prevent breakage of the LTC layer 112 caused due to a crack and the like resulting from external impact applied to the device 1, for example. A problem of breakage of the LTC layer 112 caused due to a crack and the like resulting from heat generated when the LED element 2 is mounted can also be prevented. Thus, the device 1 can provide high reliability.

(v) The ceramic filler contained in the LTC layer 112 has a small difference in thermal expansion from the HTC layer 110. The difference in thermal expansion coefficient between the porous layer 11B and the dense layer 11A can thus be set to be within 1×10⁻⁶/K. With this structure, even when heat is generated during driving of the device 1, delamination between the porous layer 11B and the dense layer 11A caused due to the difference in thermal expansion therebetween, and cracking occurring at an interface between the porous layer 11B and the dense layer 11A can be prevented.

<Method for Manufacturing LTCC/HTCC Laminated Substrate 10>

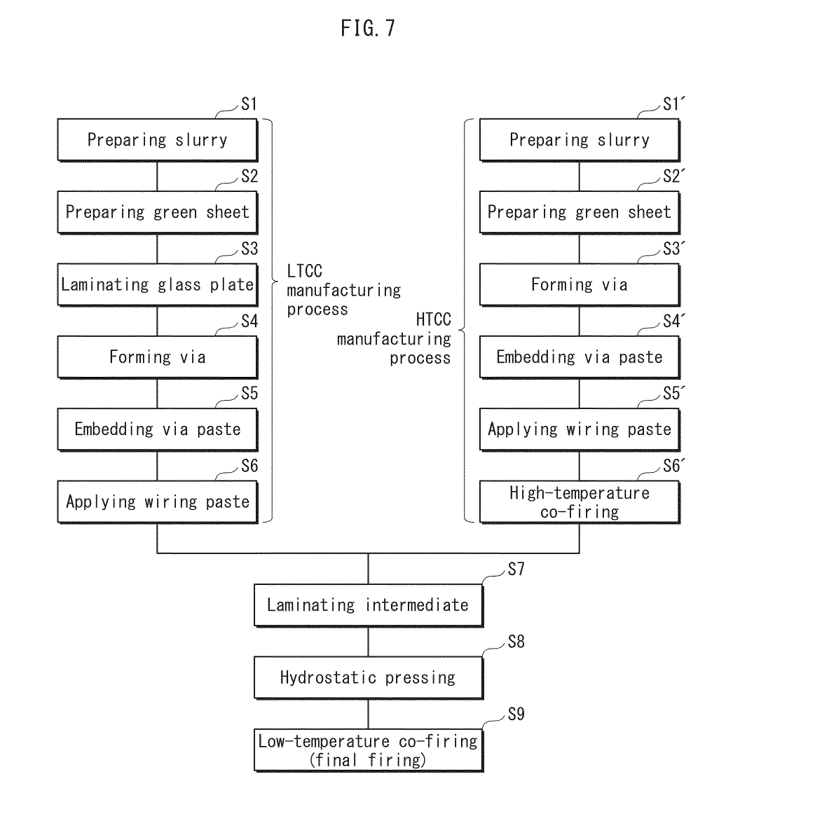

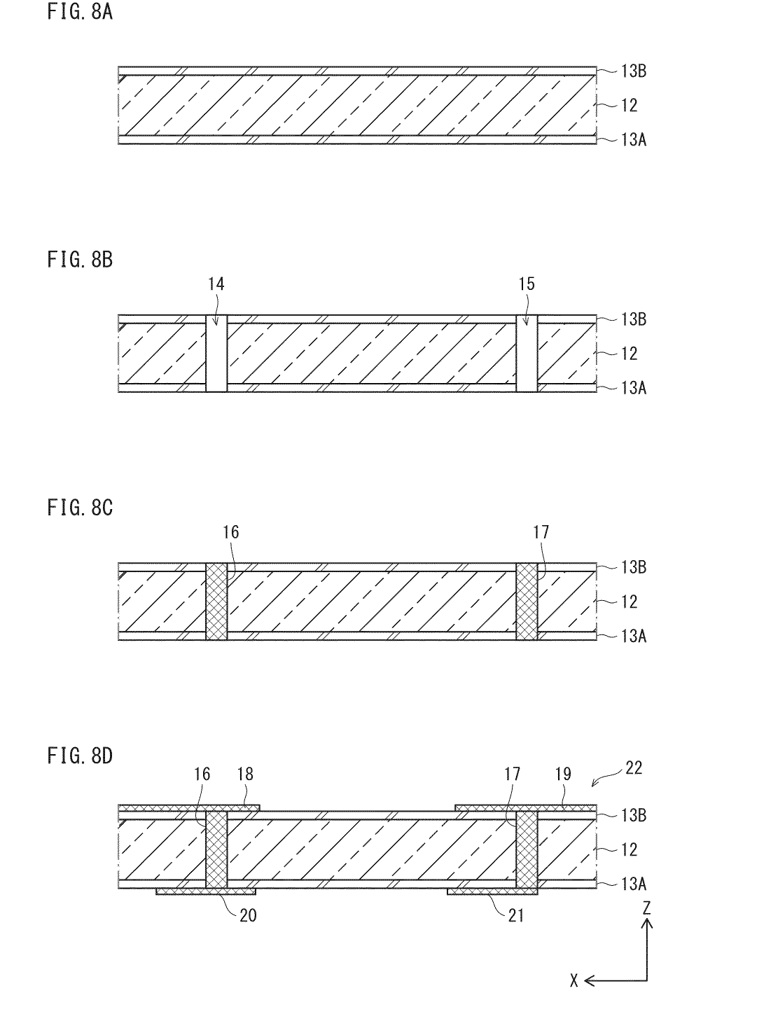

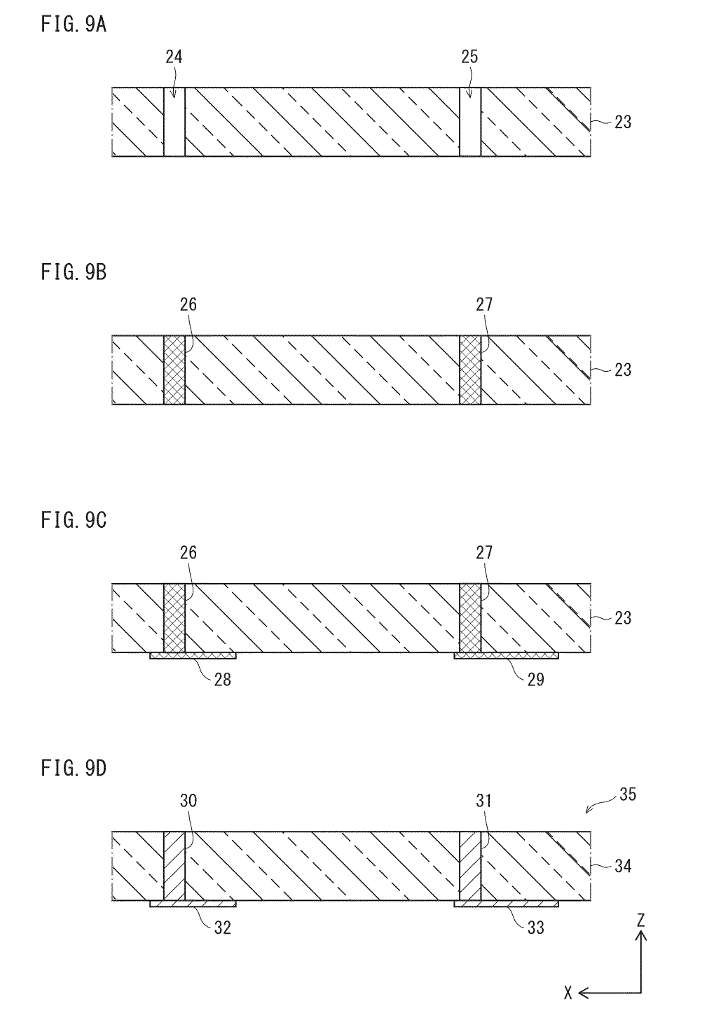

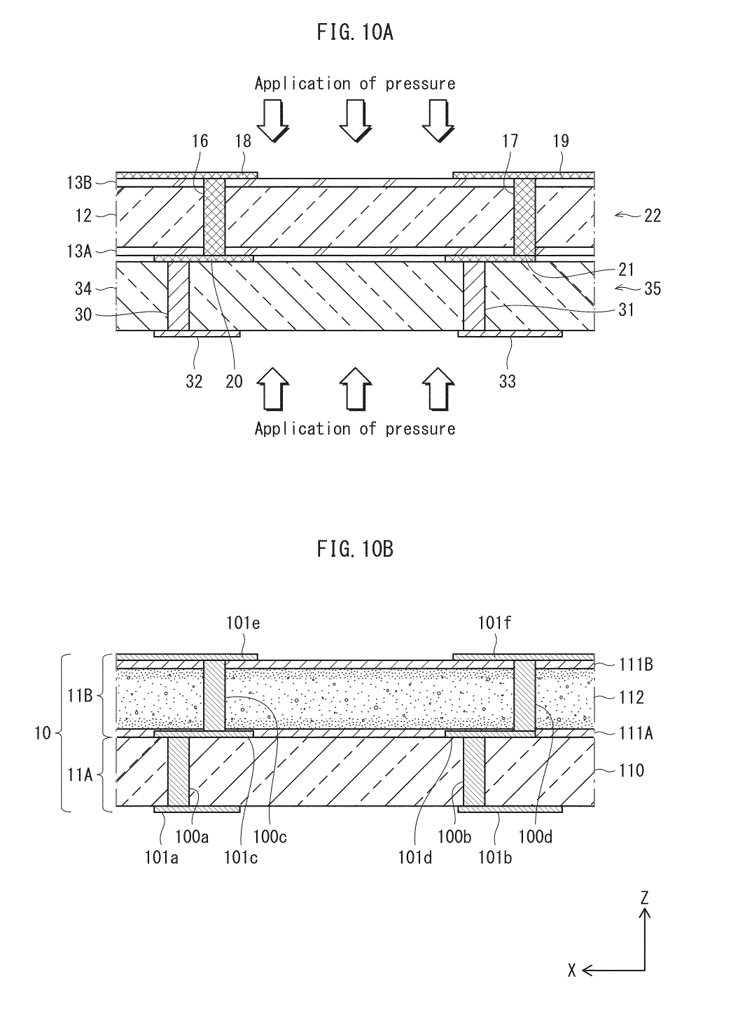

The following describes an example of a method for manufacturing the LTCC/HTCC laminated substrate 10, with use of FIGS. 6, 7, 8A-8D, 9A-9D, 10A, and 10B. FIG. 6 is a graph showing a range of a preferable glass blending ratio in the LTC layer 112. FIG. 7 schematically shows steps of manufacturing the LTCC/HTCC laminated substrate 10. FIGS. 8A-8D are sectional views schematically showing a manufacturing process of a porous layer intermediate 22. FIGS. 9A-9D are sectional views schematically showing a manufacturing process of a dense layer intermediate 35. FIGS. 10A and 10B are sectional views schematically showing a manufacturing process of the LTCC/HTCC laminated substrate 10.

The LTCC/HTCC laminated substrate 10 undergoes an LTCC manufacturing process of manufacturing the porous layer intermediate 22, an HTCC manufacturing process of manufacturing the dense layer intermediate 35, and then a combining process of combining the porous layer intermediate 22 and the dense layer intermediate 35.

(Manufacturing of Porous Layer Intermediate 22)

First, base powder containing glass powder and ceramic filler, an organic binder, a plasticizer, and a solvent are mixed together to prepare slurry for LTCC.

In this case, when the HTC layer 110 is made of a particular material, it is necessary to match a thermal expansion coefficient of the LTC layer 112 with a thermal expansion coefficient of the HTC layer 110 as much as possible. The thermal expansion coefficient of the LTC layer 112 can be adjusted by blending glass having a relatively high thermal expansion coefficient with glass having a normal thermal expansion coefficient, and by blending forsterite and zirconia, which have a relatively high thermal expansion coefficient, into ceramic filler.

The following describes four blending examples of glass and ceramic filler. In each blending example, values in parentheses indicate thermal expansion coefficients. The blending example of glass and ceramic filler according to the present invention is naturally not limited to those shown in the following Examples 1-4.

### Example 1

When the HTC layer 110 is made of Al₂O₃, which has relatively high thermal expansion, a glass component 1 (9), a glass component 2 (5), and Al₂O₃ (7) are blended in a weight ratio of 30:20:50.

### Example 2

When the HTC layer 110 is made of Al₂O₃, which has relatively high thermal expansion, as an example of using Al₂O₃ and ZrO₂ as ceramic filler, a glass component 1 (9), a glass component 2 (5), Al₂O₃ (7), and ZrO₂ (10) are blended in a weight ratio of 25:25:30:20.

### Example 3

When the HTC layer 110 is made of Al₂O₃, which has relatively high thermal expansion, as an example of using Al₂O₃, forsterite (2MgO.SiO₂), and ZrO₂ as ceramic filler, a glass component 1 (5), 2MgO.SiO₂ (10), Al₂O₃ (7), and ZrO₂ (10) are blended in a weight ratio of 20:10:30:40.

### Example 4

When the HTC layer 110 is made of AlN, which has relatively low thermal expansion, as an example of using Al₂O₃ and ZrO₂ as ceramic filler, a glass component 1 (5), a glass component 2 (1), Al₂O₃ (7), and ZrO₂ (10) are blended in a weight ratio of 10:40:35:15.

(Porosity of LTC Layer 112)

The porosity of the LTC layer 112 can be adjusted by changing a glass blending ratio, a glass softening point, and a particle size of ceramic filler in a green sheet for LTCC 12 described below. Specifically, the porosity is set to fall within a range of 10% or more and 40% or less by setting the glass blending ratio to 10 wt % or more and 30 wt % or less, setting the glass softening point to a temperature that is lower than a firing temperature during low-temperature co-firing (S9 in FIG. 7) and is higher than a temperature that is lower than the firing temperature by 100° C. (firing temperature−100° C.<glass softening point<firing temperature), and setting the particle size of ceramic filler to 0.1 μm or more and 0.3 μm or less.

When the porosity exceeds 40%, the LTC layer 112 might become extremely brittle. On the other hand, the porosity of less than 10% can result in insufficient optical reflectance.

(Glass Blending Ratio in LTC Layer 112)

As shown in FIG. 6, the glass blending ratio in the LTC layer 112 is proportional to the strength (shown as the transverse rupture strength in FIG. 6) of the LTC layer 112, but is inversely proportional to the optical reflectance of the LTC layer 112. Considering balance between the strength and the optical reflectance, according to data shown in FIG. 6, it is desirable that the glass blending ratio in the LTC layer 112 fall within a range of 15 wt % or more and 35 wt % or less.

After slurry is adjusted in step S1, a flat member is coated with the slurry, for example, by a doctor blade method, such that the slurry has a thickness of 10 μm or more and 150 μm or less, and is then dried. After the dryness is checked, the flat member coated with the slurry is cut to a predetermined size to prepare the green sheet for LTCC 12 (step S2 in FIG. 7, FIG. 8A).

Next, a pair of glass-containing sheets is prepared as materials for the first glass layer 111A and the second glass layer 111B. As the pair of glass-containing sheets, glass plates 13A and 13B are used herein (FIG. 8A). By way of example, each of the glass plates 13A and 13B has a thickness of 5 μm or more and 20 μm or less, and has a final thickness of approximately 10 μm. When the glass plates 13A and 13B are each too thin, and have an extremely high softening point, adhesion between the first glass layer 111A (the second glass layer 111B) and the LTC layer 112 after completion might be reduced. On the other hand, when the glass plates 13A and 13B are too thick, the LED element 2 might not be mounted successfully on the second glass layer 111B due to lifting of glass, and the thermal resistance of the porous layer 11B might increase.

The green sheet for LTCC 12 is interposed between the glass plates 13A and 13B to manufacture a laminate (step S3 in FIG. 7, FIG. 8A).

The laminate may be configured as an integrated member in which the glass-containing sheets are disposed by applying a glass-containing solution to both surfaces of the green sheet for LTCC 12.

Alternatively, the glass plate 13A and the glass plate 13B are laminated on respective green sheets for LTCC 12 to form two double-layer sheets in advance. In this case, it suffices to prepare two double-layer sheets having substantially the same structure. By then laminating one of two green sheets for LTCC 12 each having a double-layer structure on the other one of the two green sheets for LTCC 12, the laminate can be manufactured.

Next, the laminate is pierced with a die to form via holes 14 and 15 passing from the glass plate 13A to the glass plate 13B (step S4 in FIG. 7, FIG. 8B). Piercing with a die is suitable for mass production. As a method for forming via holes, however, laser irradiation on a glass plate may also be used.

Pastes (via pastes) 16 and 17 each containing Ag and the like are embedded into the via holes 14 and 15 thus formed in accordance with screen printing (step S5 in FIG. 7, FIG. 8C). Furthermore, wiring pastes 18 to 21 are applied to a surface of each of the glass plates 13A and 13B in accordance with screen printing (step S6 in FIGS. 7, 8D).

The porous layer intermediate 22 is thus manufactured (FIG. 8D).

(Manufacturing of Dense Layer Intermediate 35)

In a similar procedure to that used in steps S1 to S3, slurry for HTCC containing a predetermined ceramic material is prepared (step S1′ in FIG. 7), and a flat member is then coated with the slurry, dried, and cut to a predetermined size to obtain a green sheet for HTCC 23 (S2′ in FIG. 7, FIG. 9A).

As in step S4, the green sheet for HTCC 23 is pierced to form via holes 24 and 25 (step S3′ in FIG. 7, FIG. 9A). The via holes 24 and 25 are filled with via pastes 26 and 27 each containing a high-melting point material for high-temperature firing in accordance with screen printing (step S4′ in FIG. 7, FIG. 9B). Furthermore, wiring pastes 28 and 29 each containing a high-melting point material for high-temperature firing are applied to a lower surface of the green sheet for HTCC 23 in accordance with screen printing (step S5′ in FIG. 7, FIG. 9C).

Then, high-temperature co-firing is performed at a relatively high temperature (1200° C. or higher, approximately 1200° C., for example) by using, for example, a small-sized electric box furnace named KBF624N1 manufactured by Koyo Thermo Systems Co., Ltd. (step S6′ in FIG. 7). By the high-temperature co-firing, the green sheet for HTCC 23, the via pastes 26 and 27, and the wiring pastes 28 and 29 are sintered to become a sintered sheet 34, sintered vias 30 and 31, and sintered wiring layers 32 and 33, respectively (FIG. 9D).

The dense layer intermediate 35 is thus manufactured (FIG. 9D).

Via pastes and wiring pastes each containing a low-melting point material for low-temperature firing that can be fired at a relatively low temperature of 1000° C. or lower may also be used. In this case, the via pastes 26 and 27, and the wiring pastes 28 and 29 should be disposed after processing in step S6′ is performed, and then the low-temperature co-firing should be performed in the following manner.

At least one of the green sheet for LTCC 12 and the green sheet for HTCC 23 may be adjusted so as to have a predetermined thickness by configuring the at least one of the green sheets as a laminate of two or more green sheets. When the green sheet for HTCC 23 is configured as a laminate of a plurality of green sheets, after each via hole is filled with a via paste, the plurality of green sheets can be integrated by pressing, for example.

(Completion of LTCC/HTCC Laminated Substrate 10)

The porous layer intermediate 22 is laminated on the dense layer intermediate 35 (step S7 in FIG. 7, FIG. 10A). Hydrostatic pressing is performed by applying pressure to the laminate of the porous layer intermediate 22 and the dense layer intermediate 35 by using a hydrostatic pressing machine (step S8 in FIG. 7, FIG. 10A).

By then performing low-temperature co-firing at a relatively low temperature (1000° C. or lower, approximately 900° C., for example), the glass plates 13A and 13B, the green sheet for LTCC 12, the sintered sheet 34, the via pastes 16 and 17, the sintered vias 30 and 31, the wiring pastes 18 to 21 and the sintered wiring layers 32 and 33 are final-fired to become the first glass layer 111A, the second glass layer 111B, the LTC layer 112, the HTC layer 110, the vias 100a to 100d, and the wiring layers 101a to 101f, respectively. The LTCC/HTCC laminated substrate 10 is thus completed (step S9, FIG. 10B).

<Method for Manufacturing Device 1>

The LTCC/HTCC laminated substrate 10 thus manufactured is prepared. The adhesive agent 5 is applied to a surface of the second glass layer 111B to mount thereon the LED element 2.

The LED element 2 is then bonded to the wiring layers 101e and 101f respectively by the bonding wires 3a and 3b. In some case, flux is used in the bonding. In the LTCC/HTCC laminated substrate 10, however, since a surface of the LTC layer 112 is covered with the second glass layer 111B, the flux does not adhere to the surface of the LTC layer 112, and thus will not deteriorate the LTC layer 112.

After the bonding, the sealing resin 4 is applied so as to cover the LED element 2, and the bonding wires 3a and 3b. The device 1 is thus manufactured (FIG. 1).

The following describes other embodiments of the present invention by mainly focusing on the differences among embodiments.

### Embodiment 2

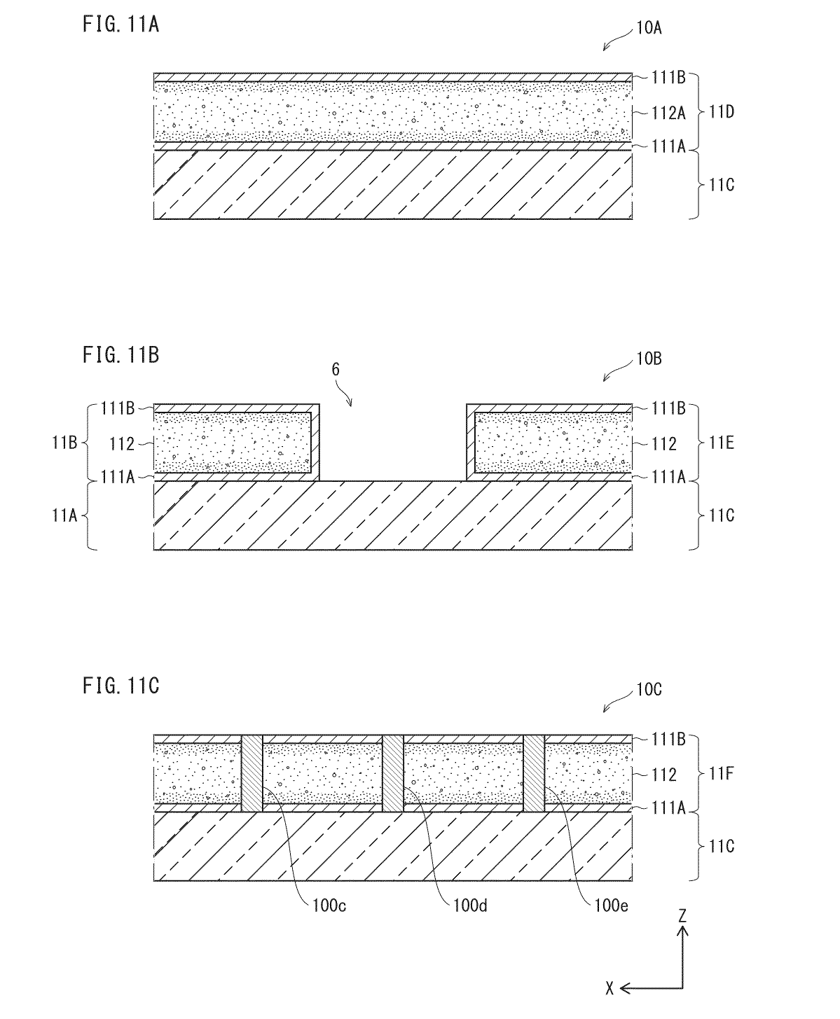

FIG. 11A is a sectional view schematically showing the structure of a substrate 10A according to Embodiment 2. The substrate 10A is designed for use as a sub-mount substrate and a support substrate for the LED element 2. The substrate 10A has a structure of the LTCC/HTCC laminated substrate 10 from which the wiring layers 101a to 101f and the vias 100a to 100d have been omitted.

Specifically, the substrate 10A includes a dense layer 11C as the HTC layer, and a porous layer 11D as the LTC layer. The porous layer 11D includes a porous ceramic layer 112A, a first glass layer 111A disposed below the porous ceramic layer 112A, and a second glass layer 111B disposed over the porous ceramic layer 112A.

The substrate 10A having the above-mentioned structure can produce effects similar to those produced in Embodiment 1. Furthermore, since wiring layers and vias are not provided on/in the porous layer 11D and the dense layer 11C, some of the steps are omitted, thereby reducing production costs.

### Embodiment 3

FIG. 11B is a sectional view schematically showing the structure of a substrate 10B according to Embodiment 3.

The substrate 10B is different from the substrate 10A according to Embodiment 2 in that a porous layer 11E having a cavity-structure portion 6 is formed so as to expose a surface of the dense layer 11C from the cavity-structure portion 6. By way of example, the LED element 2 is mounted on the surface of the dense layer 11A exposed from the cavity-structure portion 6. As the LED element 2, an LED element having a reflective film on the backside thereof is preferably used.

The substrate 10B having the above-mentioned structure can produce effects similar to those produced in Embodiments 1 and 2. Furthermore, since the LED element 2 is directly mounted on the surface of the dense layer 11C, heat generated by the LED element 2 during driving can rapidly be dissipated toward the dense layer 11C.

In addition to the use of the substrate 10B as a substrate for directly mounting the LED element 2, the substrate 10B can be used as a sub-mount substrate.

### Embodiment 4

FIG. 11C is a sectional view schematically showing the structure of a substrate 10C according to Embodiment 4.

The substrate 10C is different from the substrate 10A according to Embodiment 2 in that the vias 100c to 100e are provided only in the porous layer 11F. The porous layer 11F can be configured as the LTCC layer.

The substrate 10C can be used in an optical semiconductor device in which the LED element 2 is mounted by using chip on board (COB) technology, for example.

The substrate 10C having the above-mentioned structure can produce effects similar to those produced in Embodiments 1 and 2. Furthermore, since the vias 100c to 100e are provided, heat generated by the LED element 2 can efficiently be dissipated.

### Embodiment 5

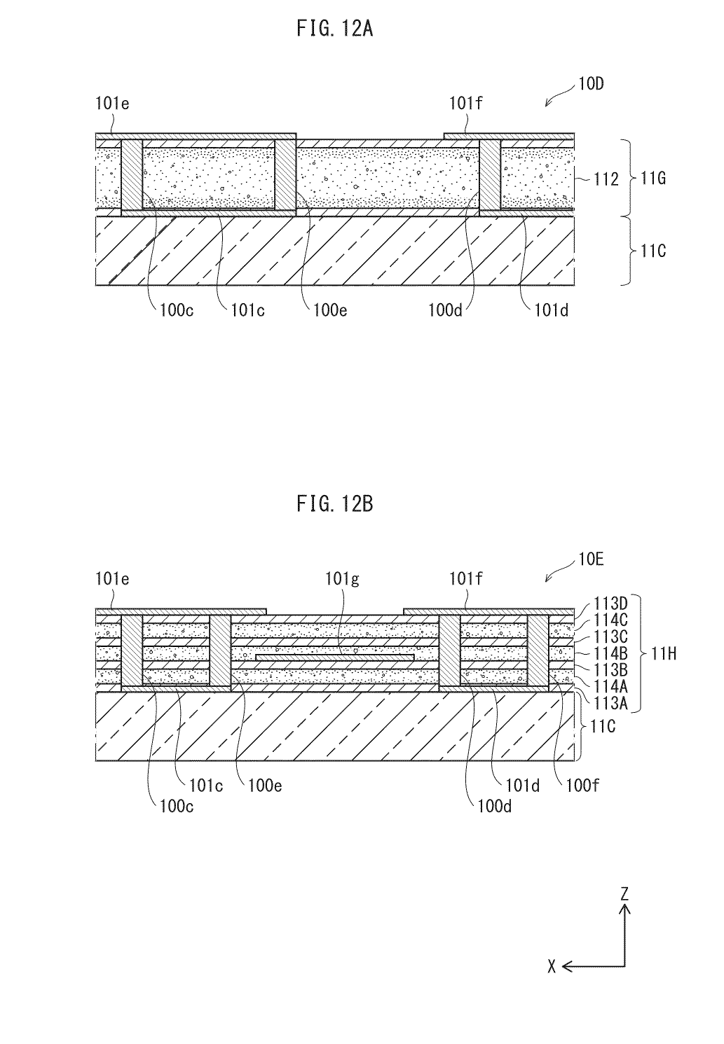

FIG. 12A is a sectional view schematically showing the structure of a substrate 10D according to Embodiment 5.

The substrate 10D has a structure which is based on the substrate 10C according to Embodiment 4, and in which the wiring layers 101c, 101d, 101e, and 101f are provided on both surfaces of the LTC layer 112 included in a porous layer 11G The porous layer 11G can be configured as the LTCC layer.

The substrate 10D having the above-mentioned structure can produce effects similar to those produced in Embodiment 4.

### Embodiment 6

FIG. 12B is a sectional view schematically showing the structure of a substrate 10E according to Embodiment 6.

The substrate 10E is a laminate of the dense layer 11C and a porous layer 1111. The porous layer 1111 includes four glass layers 113A to 113D (a first glass layer 113A, a second glass layer 113B, a third glass layer 113C, and a fourth glass layer 113D) and three porous ceramic layers (a porous ceramic layer 114A, a first porous ceramic layer 114B, and a second porous ceramic layer 114C) alternately laminated. The porous layer 1111 also includes a wiring layer 101g interposed at a part of an interface between the second glass layer 113B and the first porous ceramic layer 114B, and the vias 100c to 100f and the wiring layers 101c to 101f. The porous layer 1111 can be configured as the LTCC layer.

The substrate 10E having the above-mentioned structure can produce effects similar to those produced in Embodiment 4. Furthermore, by disposing the wiring layer 101g at a part of an interface between the glass layer 113B and the porous ceramic layer 114B, the substrate 10E can be configured as a high-density mount substrate, thereby contributing to reduction in size of the substrate 10E. In addition, by laminating the glass layers 113A to 113D, the porous layer 1111 can be improved in strength, and the thickness of the porous layer 1111 can be increased to some extent.

The substrate 10E may be used as a ceramic low-dielectric constant substrate. In this case, the substrate can exhibit high performance when it is porous. Thus, the quantity of glass component in each of the porous ceramic layers 114A to 114C should be as small as possible. The wiring layer is naturally not limited to the wiring layer 101g, and may be interposed between any pairs of a glass layer and a porous ceramic layer adjacent to each other.

In the substrate 10E, as ceramic filler contained in each of the porous ceramic layers 114A to 114C, it is desirable to use at least one material selected from the group consisting of boron oxide, silica, magnesia, lithium oxide, alumina, zinc oxide, barium oxide, strontium oxide, calcium oxide, and titania.

The number of laminated porous ceramic layers and laminated glass layers can be changed as appropriate. For example, the second porous ceramic layer 114C and the fourth glass layer 113D may be omitted, and the wiring layers 101e and 101f may be formed on the third glass layer 113C.

<Others>

The LTCC/HTCC laminated substrate 10 according to Embodiment 1, the substrate 10D according to Embodiment 5, and the substrate 10E according to Embodiment 6 can each be configured as a high-frequency wiring substrate (SMD) for transmitting a high-frequency signal by forming a wiring layer in a predetermined pattern.

The glass component contained in each of the first glass layer 111A and the second glass layer 111B infiltrates into the LTC layer 112 during firing or in other steps. When the LTC layer 112 contains a large number of pores, the quantity of glass component infiltrating into the LTC layer 112 increases, and thus the first glass layer 111A and the second glass layer 111B can become extremely thin. Even with such a structure, the effects of the present invention can be achieved, because surfaces of the LTC layer 112 in the thickness (Z) direction thereof are substantially covered with the first glass layer 111A and the second glass layer 111B.

As in each of Embodiments 1, 5, and 6, the optical semiconductor element-mounting substrate including the wiring layers 101e and 101f for connecting the LED element 2 is also referred to as “a package for an optical semiconductor element”.

Depending on a material for the dense layer intermediate used in the manufacturing step, and a condition of firing profile setting in the high-temperature co-firing step (S6′) and the like, the dense layer intermediate 35 can be formed substantially as the dense layer by performing high-temperature firing in the high-temperature co-firing step (S6′). The manufacturing method according to Embodiment 1 may substantially form the dense layer in step S6′ as described above.

The terms “glass” and “ceramic” appearing in the present specification respectively refer to an amorphous material and a crystalline aggregate.

The sealing resin for sealing the LED element is not essential, and thus may be omitted.

The present invention is widely applicable as an optical semiconductor element-mounting substrate on which an LED element, for example, is mounted, and an optical semiconductor device including the optical semiconductor element-mounting substrate.

Although the present invention has been fully described by way of examples with reference to the accompanying drawings, it is to be noted that various changes and modifications will be apparent to those skilled in the art. Therefore, unless such changes and modifications depart from the scope of the present invention, they should be construed as being included therein.

What is claimed is:

1. An optical semiconductor element-mounting substrate comprising a laminate of a dense layer and a porous layer, wherein
the porous layer includes:
a first glass layer on the dense layer;
a porous ceramic layer on the first glass layer; and
a second glass layer on the porous ceramic layer,
the porous ceramic layer contains a glass component and ceramic filler, and has a porosity of 10% or more and 40% or less, and
the dense layer contains a ceramic component, and has a higher transverse rupture strength than the porous ceramic layer.

2. The optical semiconductor element-mounting substrate of claim 1, wherein
the porous ceramic layer is made of a low-temperature fired ceramic containing the glass component and the ceramic filler.

3. The optical semiconductor element-mounting substrate of claim 1, wherein
a difference in thermal expansion coefficient between the porous ceramic layer and the dense layer is 1×10⁻⁶/K or less.

4. The optical semiconductor element-mounting substrate of claim 1, wherein
the porous layer has a reflectance of 85% or more to light having a wavelength of 380 nm or more and 780 nm or less.

5. The optical semiconductor element-mounting substrate of claim 1, wherein
the porous ceramic layer has a thickness of 20 μm or more and 150 μm or less.

6. The optical semiconductor element-mounting substrate of claim 1, wherein
a concentration of the glass component at surfaces of the porous ceramic layer in a thickness direction thereof is higher than an average concentration of the glass component in the porous ceramic layer.

7. The optical semiconductor element-mounting substrate of claim 1, wherein
the glass component is at least one material selected from the group consisting of borosilicate glass, silica glass, soda-lime glass, borosilicate zinc glass, aluminoborosilicate glass, aluminosilicate glass, and phosphate glass.

8. The optical semiconductor element-mounting substrate of claim 1, wherein
the ceramic filler is at least one material selected from the group consisting of alumina, zirconia, titanium oxide, zinc oxide, forsterite, enstatite, celsian, slawsonite, anorthite, diopside, gahnite, spinel, willemite, mullite, cordierite, and solid solutions of any of the stated materials.

9. The optical semiconductor element-mounting substrate of claim 1, wherein
the dense layer is made of a high-temperature fired ceramic containing the ceramic component.

10. The optical semiconductor element-mounting substrate of claim 9, wherein
the high-temperature fired ceramic is at least one material selected from the group consisting of alumina and aluminum nitride.

11. The optical semiconductor element-mounting substrate of claim 1, wherein
the porous layer includes a cavity-structure portion having a depth in a thickness direction of the porous layer.

12. The optical semiconductor element-mounting substrate of claim 1, wherein
the porous layer has at least one via, each via penetrating through the porous layer in a thickness direction thereof.

13. The optical semiconductor element-mounting substrate of claim 1, wherein
a first porous ceramic layer, a third glass layer, a second porous ceramic layer, and a fourth glass layer are located on the porous layer in the stated order, and
a wiring layer is located at a part of an interface between the second glass layer and the first porous ceramic layer.

14. An optical semiconductor device comprising:
the optical semiconductor element-mounting substrate of claim 1; and
an optical semiconductor element mounted on the optical semiconductor element-mounting substrate of claim 1.

15. A method for manufacturing an optical semiconductor element-mounting substrate, comprising:
interposing a green sheet between a pair of glass-containing sheets to form a porous layer intermediate, the green sheet containing ceramic filler and a glass component;
laminating a dense layer intermediate containing a ceramic component on one of the glass-containing sheets;
firing the porous layer intermediate and the dense layer intermediate to respectively form a porous layer and a dense layer, the porous layer including a pair of glass layers and a porous ceramic layer interposed between the pair of glass layers, wherein
in forming the porous layer intermediate, the green sheet has a glass blending ratio, a glass softening point, and a particle size of the ceramic filler each adjusted so that the porous ceramic layer has a porosity of 10% or more and 40% or less, and
in forming the dense layer, a material providing the dense layer with a higher transverse rupture strength than the porous ceramic layer is used as the ceramic component.

16. The method for manufacturing an optical semiconductor element-mounting substrate of claim 15, wherein
the glass blending ratio is 10 wt % or more and 30 wt % or less,
the glass softening point is lower than a firing temperature in firing the porous layer intermediate and the dense layer intermediate, and is higher than a temperature that is lower than the firing temperature by 100° C., and
the particle size of the ceramic filler is 0.1 μm or more and 0.3 μm or less.

16. The method for manufacturing an optical semiconductor element-mounting substrate of claim 15, wherein
in firing the porous layer intermediate, the porous ceramic layer is formed by low-temperature co-firing.

17. The method for manufacturing an optical semiconductor element-mounting substrate of claim 15, wherein
each of the glass-containing sheets is a glass plate having a thickness of 5 μm or more and 20 μm or less.

18. The method for manufacturing an optical semiconductor element-mounting substrate of claim 15, wherein
a thickness of the green sheet is adjusted so that the porous ceramic layer has a thickness of 10 μm or more and 150 μm or less.

19. The method for manufacturing an optical semiconductor element-mounting substrate of claim 15, wherein
a glass component contained in each of the glass-containing sheets is infiltrated into the green sheet in firing the porous layer intermediate, so that a concentration of the glass component at surfaces of the porous ceramic layer in a thickness direction thereof is higher than an average concentration of the glass component in the porous ceramic layer.

20. The method for manufacturing an optical semiconductor element-mounting substrate of claim 15, wherein
the glass component is at least one material selected from the group consisting of borosilicate glass, silica glass, soda-lime glass, borosilicate zinc glass, aluminoborosilicate glass, aluminosilicate glass, and phosphate glass.

21. The method for manufacturing an optical semiconductor element-mounting substrate of claim 15, wherein
the ceramic filler is at least one material selected from the group consisting of alumina, zirconia, titanium oxide, zinc oxide, forsterite, enstatite, celsian, slawsonite, anorthite, diopside, gahnite, spinel, willemite, mullite, cordierite, and solid solutions of any of the stated materials.

22. The method for manufacturing an optical semiconductor element-mounting substrate of claim 15, wherein
the ceramic component is at least one material selected from the group consisting of alumina and aluminum nitride.

23. A method for manufacturing an optical semiconductor device, comprising
mounting a light-emitting element above the porous layer included in the optical semiconductor element-mounting substrate manufactured by the method for manufacturing an optical semiconductor element-mounting substrate of claim 15.
